(19) United States
(12) Patent Application Publication
(10) Pub. No.: US 2026/0349005 A1
(43) Pub. Date: Nov. 5, 2026

(54) DEVICE BOARD

(71) Applicant: ADVANTEST CORPORATION, Tokyo (JP)

(72) Inventor: Keiji NARUMI, Tokyo (JP)

(21) Appl. No.: 19/550,539

(22) Filed: Feb. 26, 2026

(30) Foreign Application Priority Data
Apr. 30, 2025 (JP) 2025-075626

(51) Int. Cl. G01R 1/04; G01R 31/28

(52) U.S. Cl. CPC G01R 1/0408; G01R 31/2834

(57) ABSTRACT

A device board is detachable from the frame of an automatic test apparatus. The device board includes a socket board, a socket guide, and a locking mechanism. The locking mechanism is structured to switch between at least a first state and a second state. The locking mechanism is configured to couple the socket board and the socket guide to each other in the first state. The locking mechanism is configured to be capable of decoupling the socket board from the socket guide and to couple the socket board to the frame of the automatic test apparatus in the second state.

### REFERENCE TO RELATED APPLICATIONS

The present invention claims priority under 35 U.S.C. § 119 to Japanese Application No. 2025-075626 filed on Apr. 30, 2025, the entire contents of which are incorporated herein by reference.

### BACKGROUND

### 1. Technical Field

The present disclosure relates to a device board.

### 2. Description of the Related Art

An automatic test equipment (ATE) is used for testing various semiconductor devices such as memory and CPUs (Central Processing Units). The ATE supplies test signals to a semiconductor device under test (hereinafter referred to as DUT), measures the DUT's response to the test signals, determines whether the DUT is acceptable, and identifies defective portions.

In recent years, DRAM (Dynamic Random Access Memory) has been increasing in speed. In GDDR (Graphics Double Data Rate) memory used in graphic boards, the GDDR6X standard achieves a transmission speed of 21 Gbps using the NRZ (Non Return to Zero) method.

In next-generation GDDR7, PAM4 (Pulse Amplitude Modulation 4) is adopted, and the transmission speed is increased up to 40 Gbps. The NRZ method is also advancing in speed year by year, and in the next generation, speeds of approximately 28 Gbps are expected.

Patent Document 1 (Japanese Patent Application Publication No. 2024-014522) discloses an interface device and an automatic test equipment capable of accurately testing high-speed devices. In this interface device, the socket board and the pin electronics circuit are connected via an interposer and wiring.

A component referred to as a device board or a DSA (Device Specific Adapter) is provided at a connection point of an interface device of an automatic test apparatus with a DUT. The device board includes a socket board (socket PCB), a plurality of sockets, and a socket guide. The socket guide is attached on the socket board so as to sandwich the plurality of sockets between the socket guide and the socket board. The plurality of sockets are positioned at appropriate positions by the socket guide.

The sockets in the device board are replaceable so as to measure DUTs having different pin layouts or to be replaced with new ones when worn out. In a conventional configuration, when replacing the sockets, it is necessary to remove the entire device board from the frame of the automatic test apparatus, disassemble the device board, and then replace the sockets. This requires a lot of effort from an operator and can be said to have poor maintainability.

### SUMMARY

The present disclosure has been made in such circumstances, and one exemplary object of an aspect thereof is to provide a device board in which a socket can be easily replaced.

One aspect of the present disclosure relates to a device board detachable from a frame of an automatic test apparatus. The device board includes a socket board, a socket guide, and a locking mechanism structured to switch between at least a first state and a second state. The locking mechanism is configured to couple the socket board and the socket guide to each other in the first state. In the second state, the locking mechanism is configured to decouple the socket board from the socket guide and couple the socket board to the frame of the automatic test apparatus.

Another aspect of the present disclosure relates to a lock pin. The lock pin is used with a socket board and a socket guide to constitute a device board. The lock pin is structured to be rotatably attachable to the socket board and includes a frame lock key and a socket guide lock key. The frame lock key is configured to be insertable into and removable from a frame keyhole provided in a frame when the lock pin is at a predetermined first angular position corresponding to a first state, and the frame lock key is configured to be lockable to the frame keyhole when the lock pin is at a predetermined second angular position corresponding to a second state. The socket guide lock key is configured to be insertable into and removable from a socket guide keyhole provided in the socket guide when the lock pin is at the second angular position, and the socket guide lock key is configured to be lockable to the socket guide keyhole when the lock pin is at the first angular position.

It is to be noted that any arbitrary combination or rearrangement of the above-described structural components and so forth is effective as and encompassed by the present embodiments. Moreover, all of the features described in this summary are not necessarily required by embodiments, so that the embodiment may also be a sub-combination of these described features. In addition, embodiments may have other features not described above.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures.

FIG. 1 is a diagram illustrating an automatic test equipment according to one embodiment.

FIG. 2 is a cross-sectional view of an interface device according to one embodiment.

FIG. 3 is a diagram illustrating a front-end module according to one embodiment.

FIG. 4 is a perspective view showing an example configuration of the FEU in FIG. 3.

FIG. 5 is a cross-sectional view showing an example configuration of the FEU in FIG. 3.

FIG. 6 is a cross-sectional view showing an example of connection between a pin electronics IC and a socket (DUT).

FIG. 7 is a cross-sectional view of a socket board according to the embodiment.

FIG. 8 is a diagram showing a layout of a plurality of second pads on the second surface of the socket PCB.

FIG. 9 is a diagram illustrating a modified example of the layout of a plurality of second pads on the second surface of the socket PCB.

FIG. 10 is a perspective view illustrating the layout of a socket board according to an embodiment.

FIG. 11 is a plan view illustrating the layout of a socket board according to an embodiment.

FIG. 12 is a plan view illustrating the layout of a socket board according to a comparative technique.

FIG. 13 is a plan view illustrating the layout of a socket board according to a modified example.

FIG. 14 is an exploded perspective view of an interface device according to an embodiment.

FIG. 15 is a diagram illustrating connection between a device board and a front-end module according to a comparative technology.

FIG. 16 is an exploded perspective view of a device board according to an embodiment.

FIG. 17 is a perspective view showing the device board in a first state.

FIG. 18 is a perspective view showing the device board in a second state.

FIG. 19 is a perspective view showing a lock pin as a locking mechanism.

FIG. 20 is a cross-sectional view of a socket PCB to which the lock pin is attached.

FIG. 21 is a perspective view showing a state of the interface device in the first state.

FIG. 22 is a perspective view showing a state of the interface device in the second state.

FIG. 23 is a diagram illustrating the first state and the second state of the lock pin.

### DETAILED DESCRIPTION

### Outline of Embodiment

An outline of several example embodiments of the disclosure follows. This outline is provided for the convenience of the reader to provide a basic understanding of such embodiments and does not wholly define the breadth of the disclosure. This outline is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “one embodiment” may be used herein to refer to a single embodiment or multiple embodiments of the disclosure.

A device board according to an embodiment is detachable from a frame of an automatic test apparatus. The device board includes a socket board, a socket guide, and a locking mechanism structured to switch between at least a first state and a second state. The locking mechanism is configured to couple the socket board and the socket guide to each other in the first state, and the locking mechanism is configured to decouple the socket board from the socket guide and couple the socket board to the frame of the automatic test apparatus in the second state.

According to this configuration, by setting the locking mechanism to the second state, only the socket guide can be removed while the socket board remains coupled to the frame. This allows operations such as replacement of a socket to be performed, and workability can be improved.

In the present disclosure, the “locking mechanism” may include: (i) a screw or a bolt configured to fix components by fastening; (ii) a claw or a hook being a structure configured to fix components to each other by hooking; (iii) a stopper being a structure configured to physically limit movement; (iv) a spring mechanism configured to hold a component at a predetermined position using a force of a spring; and (v) a latch mechanism being a structure configured to be automatically fixed after a certain operation.

In one embodiment, the locking mechanism may be a rotatable lock pin. The lock pin may include an end portion protruding from a side of the socket board, and the lock pin may be structured to maintain a state in which the socket board and the socket guide are coupled to each other when the lock pin is at a predetermined first angular position corresponding to the first state. Furthermore, the lock pin may be configured to engage the end portion with the frame and decouple the socket board from the socket guide when the lock pin is at a predetermined second angular position corresponding to the second state. The first angular position and the second angular position may have a certain range.

According to this configuration, by setting the lock pin to the second angular position, only the socket guide can be removed.

In one embodiment, the locking mechanism may be a rotatable lock pin. The lock pin may include: a frame lock key structured to be insertable into and removable from a frame keyhole provided in a frame when the lock pin is at a predetermined first angular position corresponding to a first state, and the frame lock key being configured to be lockable to the frame keyhole when the lock pin is at a predetermined second angular position corresponding to a second state; and a socket guide lock key structured to be insertable into and removable from a socket guide keyhole provided in the socket guide when the lock pin is at the second angular position, and the socket guide lock key being configured to be lockable to the socket guide keyhole when the lock pin is at the first angular position.

In one embodiment, a rotatable range of the lock pin may be limited, and the first angular position and the second angular position may be located at both ends of the rotatable range of the lock pin. This uniquely determines the first angular position and the second angular position, and thus workability of switching between the first state and the second state can be improved.

In one embodiment, the first angular position and the second angular position may be separated from each other by 180° or more. More preferably, the first angular position and the second angular position may be separated from each other by 250° to 290°.

In one embodiment, a rotation axis of the lock pin may be oriented in a horizontal direction in a state where the device board is assembled to the frame. A rotatable range of the lock pin may be determined so as to include a 12 o'clock direction of a clock, and the first angular position and the second angular position may be located at both ends of the rotatable range. Accordingly, when switching between the first angular position and the second angular position, it is necessary to rotate the lock pin through the 12 o'clock direction against gravity. Therefore, even if vibration or the like acts on the device board, it is possible to prevent the first state and the second state from being accidentally switched.

In one embodiment, openings may be formed in the socket board and the socket guide at positions corresponding to screw holes provided in the frame, and the socket guide and the socket board may be configured to be fastened together to the frame by screws.

In one embodiment, the socket board may include two locking mechanisms. The socket guide and the socket board may be configured to be fastened together to the frame by two screws. The two locking mechanisms may be arranged at a first diagonal of a rectangle, and the two screws may be arranged at a second diagonal of the rectangle.

An automatic test apparatus according to an embodiment includes any of the device boards described above.

A lock pin according to an embodiment is used with a socket board and a socket guide to constitute a device board. The lock pin is structured to be rotatably attachable to the socket board and may include: a frame lock key configured to be insertable into and removable from a frame keyhole provided in a frame when the lock pin is at a predetermined first angular position, and the frame lock key being configured to be lockable to the frame keyhole when the lock pin is at a predetermined second angular position; and a socket guide lock key configured to be insertable into and removable from a socket guide keyhole provided in the socket guide when the lock pin is at the second angular position, and the socket guide lock key being configured to be lockable to the socket guide keyhole when the lock pin is at the first angular position.

A socket board according to an embodiment is configured to be attachable with the lock pin described above.

### EMBODIMENTS

Preferred embodiments will be described below with reference to the drawings. The same or equivalent components, members, and processes shown in the drawings are assigned the same reference numerals, and redundant descriptions will be omitted as appropriate. The embodiments are illustrative and are not intended to limit the disclosure or the invention, and not all features and combinations described in the embodiments are necessarily essential to the disclosure or the invention.

The dimensions (such as thickness, length, and width) of the respective components shown in the drawings may be enlarged or reduced as appropriate for ease of understanding. Furthermore, the dimensions of multiple components do not necessarily reflect their relative size relationship, and it is possible that a member A, although drawn thicker than another member B in the drawings, is in fact thinner than member B.

In the present specification, the expression “a state in which member A is connected to member B” includes not only the case where member A and member B are physically and directly connected, but also the case where they are indirectly connected via other members, as long as such connection does not substantially affect their electrical connection state or impair the function or effect achieved by their combination.

Similarly, the expression “a state in which member C is connected (or provided) between member A and member B” includes not only the case where member A and member C or member B and member C are directly connected, but also the case where they are indirectly connected via other members, as long as such connection does not substantially affect their electrical connection state or impair the function or effect achieved by their combination.

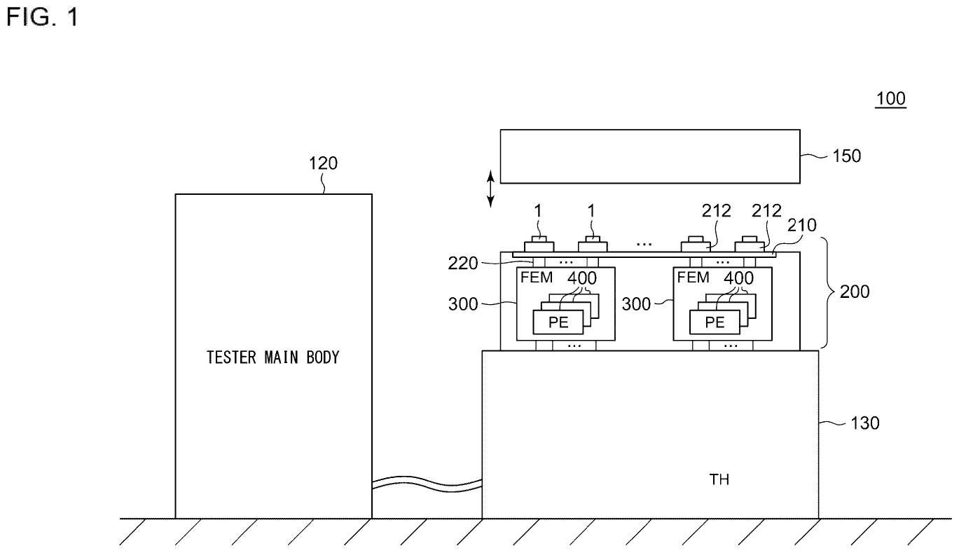

FIG. 1 is a diagram illustrating an automatic test equipment 100 according to the embodiment. The automatic test equipment 100 includes a tester 120, a test head 130, a handler 150, and an interface device 200.

The tester 120 performs overall control of the automatic test equipment 100. Specifically, the tester 120 executes a test program, controls the test head 130 and the handler 150, and collects measurement results.

The handler 150 loads the DUT 1 into the interface device 200 and unloads the tested DUT 1 from the interface device 200. The handler 150 also sorts the DUT 1 into acceptable and defective devices.

The test head 130 includes hardware that generates test signals to be supplied to the DUT 1 and detects signals from the DUT (referred to as device signals). It may also include a power supply circuit that generates supply voltages to be provided to the DUT 1 and the interface device 200.

The interface device 200 includes a device board 210, wiring 220, and a front-end module 300.

In the present embodiment, a plurality of pin electronics ICs (PE-ICs) 400 are provided not within the test head 130 but in the interface device 200. The pin electronics IC 400 is an application-specific integrated circuit (ASIC) in which a driver that generates test signals and a comparator that receives device signals are integrated. The test signals and device signals may be implemented as NRZ signals or PAM4 signals.

More specifically, the plurality of pin electronics ICs 400 are modularized. This module is referred to as the front-end module 300.

The device board 210 has a rectangular shape in a plan view, and a plurality of sockets 212 are provided on the device board 210. The DUT 1 is mounted in the socket 212. The front-end module 300 and the socket 212 are connected to each other via a wiring 220.

The above describes the configuration of the automatic test equipment 100.

According to the automatic test equipment 100, by incorporating the front-end module 300, in which the plurality of pin electronics ICs 400 are modularized, into the interface device 200, the pin electronics ICs 400 can be placed in close proximity to the DUT 1. As a result, the transmission distance of the test signals and the device signals can be significantly shortened compared to conventional configurations.

For example, in a conventional automatic test equipment, the pin electronics IC and the socket board are connected by a coaxial cable having a length of about 500 mm to 600 mm. In contrast, in the present embodiment, the length of the wiring 220 can be shortened to about 100 mm to 150 mm. This significantly reduces the loss of high-frequency components and enables transmission of high-speed test and device signals. The automatic test equipment 100, including the interface device 200, can test high-speed memory operating at more than 20 Gbps.

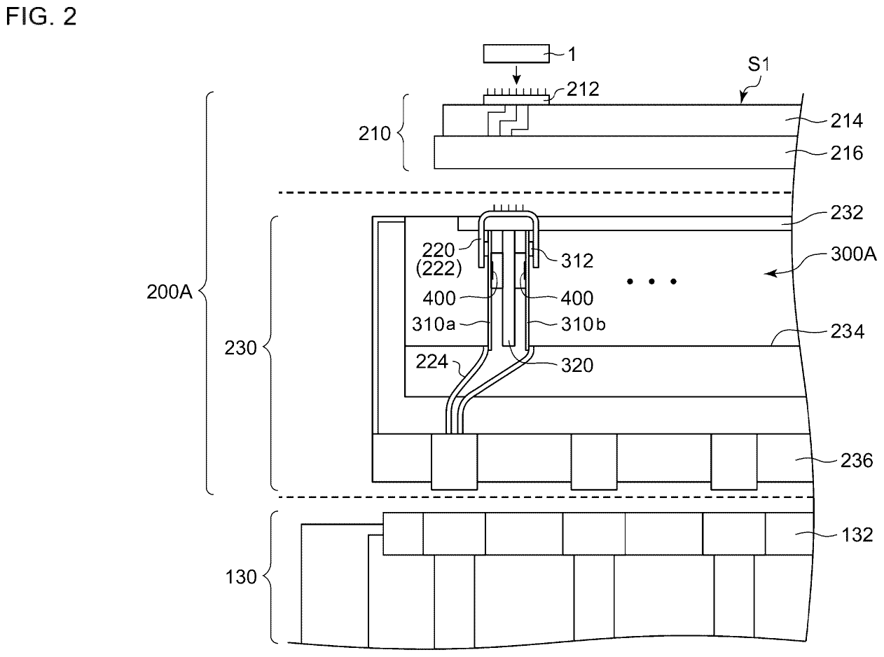

FIG. 2 is a cross-sectional view of an interface device 200A according to an embodiment. FIG. 2 shows only a configuration related to one DUT. In this embodiment, the interface device 200A includes a motherboard 230 and a device board 210 detachable from the motherboard 230. The device board 210 is also referred to as a DSA (Device Specific Adapter) and includes a socket (also referred to as a socket guide) 212 which is a mechanical component, a socket printed circuit board (socket PCB) 214, and a socket-board-side connector 216.

The front-end module 300A includes a plurality of printed circuit boards (pin electronics PCBs) 310 on which pin electronics ICs 400 are mounted. The pin electronics PCBs 310 are arranged in a direction perpendicular to a surface (front surface and back surface) of the DUT, in other words, a surface S1 of the device board 210. In the present embodiment, the device board 210 is horizontal to the ground, and thus the pin electronics PCBs 310 are arranged to be parallel to the direction of gravity. Note that the front-end module 300A may be arranged in the ATE 100 such that the surface S1 of the device board 210 faces a direction intersecting or orthogonal to an installation surface of the ATE 100 (hereinafter also referred to as “vertical installation of the device board”).

The front-end module 300A further includes a plate-shaped cooling device (hereinafter referred to as a cold plate) 320. The cold plate 320 has a flow path through which a coolant circulates.

The pin electronics PCBs 310a and 310b and the cold plate 320 are laminated in such a manner that the pin electronics ICs 400 are thermally coupled to the cold plate 320.

The motherboard 230 includes a socket-board-side connector 232, a spacing frame 234, and a relay connector 236. The front-end module 300A is fixed to the spacing frame 234. The relay connector 236 is electrically and mechanically connected to a test-head-side connector 132.

As will be described in detail later, the wiring 220 may use a cable made of a flexible printed circuit (FPC), also referred to as an FPC cable, instead of a conventional coaxial cable.

On the other hand, in the wiring 224 between the pin electronics PCB 310 and the relay connector 236, only control signals to the pin electronics ICs 400 are transmitted, and test signals and device signals are not transmitted. Therefore, the wiring 224 may use coaxial cables.

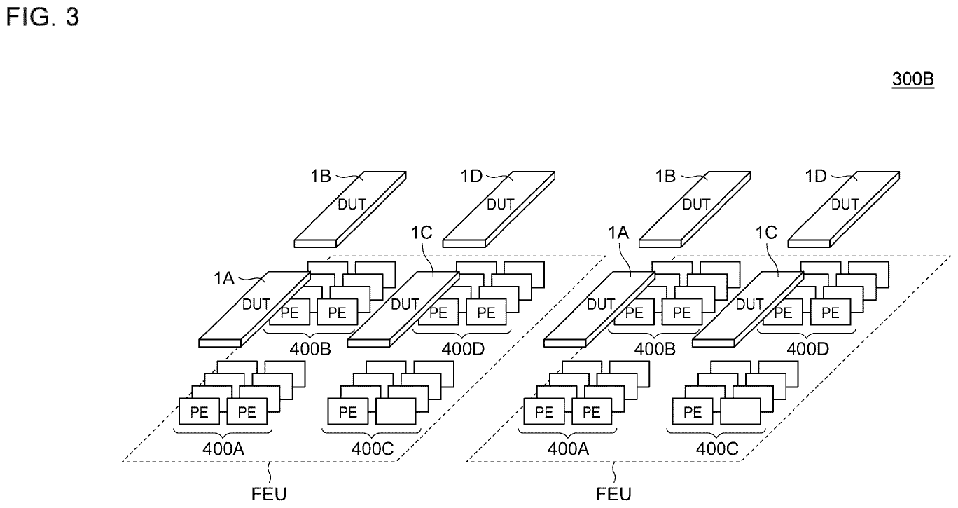

FIG. 3 illustrates a front-end module 300B according to one embodiment.

For each DUT1, 2×M (M≥1 ) pin electronics ICs 400 are assigned. The multiple DUTs and pin electronics ICs 400 are distinguished as necessary by appending subscripts A through D. In this example, assuming that DUT1 has 192 input/output terminals (I/Os), and that each pin electronics IC 400 has 24 I/Os, 192/24=8 pin electronics ICs 400 (i.e., M=4) are assigned per DUT.

The front-end module 300B is divided and configured per N (N≥2) DUTs, and each division unit is referred to as a front-end unit (FEU). In this example, each FEU comprises a block corresponding to four DUTs, and each FEU includes 2×M×N=2×4×4=32 pin electronics ICs 400.

FIG. 3 shows two FEUs, but in practice, the front-end module 300B may include two or more FEUs. For example, in an ATE capable of measuring 64 DUTs simultaneously, 64/4=16 FEUs are provided, and the entire front-end module 300B is equipped with 64×192 I/Os=12,288 I/Os.

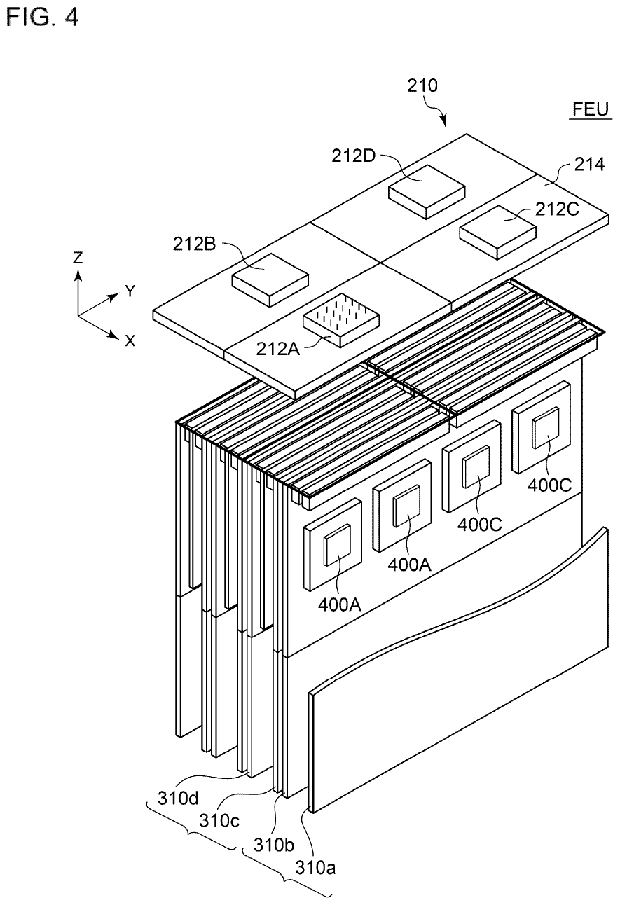

FIG. 4 is a perspective view illustrating an example configuration of the FEU in FIG. 3. The sockets 212A to 212D corresponding to the four DUTs are arranged in a two-row, two-column matrix. Focusing on one DUT 1A, the eight pin electronics ICs 400A assigned to it are mounted in pairs on four pin electronics PCBs 310a to 310d arranged in the X direction. The socket PCB 214 on which the sockets 212 are mounted may be divided per DUT, or a single socket PCB 214 corresponding to four DUTs may be configured as an integrated board.

The two pin electronics ICs 400A mounted on a single pin electronics PCB 310 are arranged in the Y direction. The two pin electronics ICs 400A are positioned equidistant from the DUT 1A.

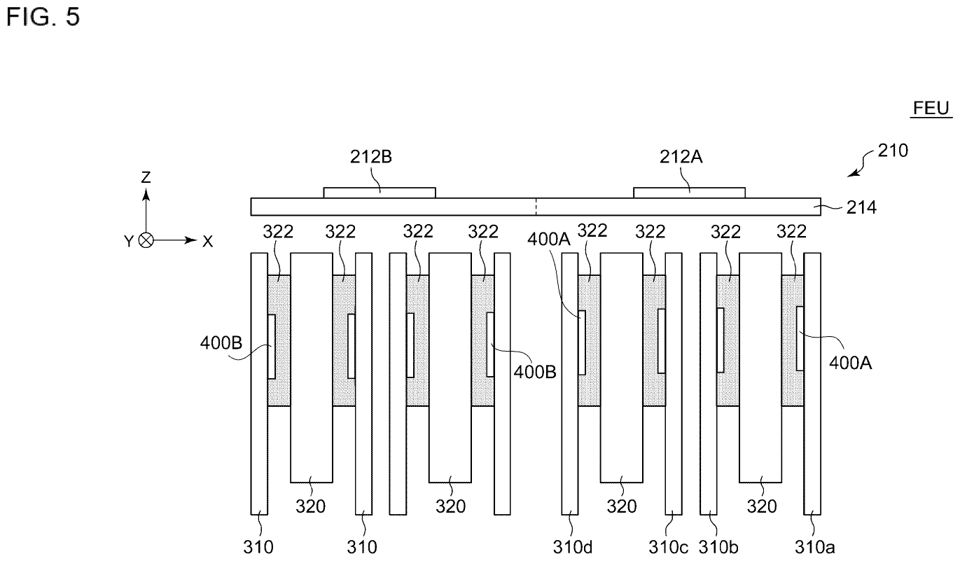

FIG. 5 is a cross-sectional view illustrating an example configuration of the FEU in FIG. 3. As shown in FIG. 2, a cold plate 320 is provided between the two pin electronics PCBs 310a and 310b. Similarly, another cold plate 320 is also provided between the two pin electronics PCBs 310c and 310d. As described above, the pin electronics ICs 400 are mounted on locations on the pin electronics PCBs 310 close to the device board 210. In order to improve cooling efficiency, the pin electronics ICs 400 may be implemented as bare chips, and the pin electronics ICs 400 are thermally coupled to the cold plate 320 via a thermal interface material (TIM) 322.

When the FEU is viewed in plan from above along the Y-axis direction, the DUT center—namely the socket 212A—is located at the center of four (M) pin electronics PCBs 310a to 310d, which are stacked along the X direction.

The above describes the configuration of the FEU.

The advantages of this FEU will now be described. Focusing on the DUT 1A, designated with the subscript A, by mounting the plurality of pin electronics ICs 400A (eight in this example) corresponding to one DUT 1A in pairs on each of the four pin electronics PCBs 310a to 310d, the distance from each of the eight pin electronics ICs 400A to the socket 212A can be made uniform. As a result, the loss of the transmission lines from each pin electronics IC 400A to the socket 212A (i.e., DUT 1A) can be made uniform, enabling accurate testing.

Next, the electrical connection between the pin electronics ICs 400 and the socket 212 will be described.

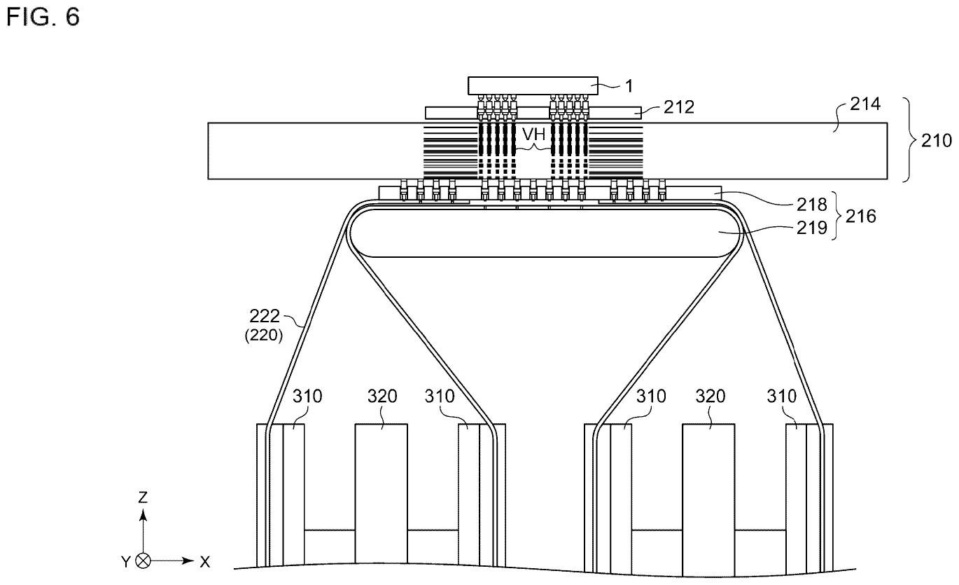

FIG. 6 is a cross-sectional view illustrating an example of the connection between the pin electronics IC and the socket (DUT 1). The transmission line through which the test signals and device signals propagate, namely the wiring 220 between the pin electronics PCB 310 and the device board 210, uses an FPC cable 222.

When coaxial cables are used as the wiring 220 between the pin electronics PCB 310 and the device board 210, the minimum distance between the pin electronics PCB 310 and the device board 210 is restricted due to the rigidity of the coaxial cables. In contrast, by using the FPC cable 222, its flexibility allows the distance h between the pin electronics PCB 310 and the device board 210 to be reduced compared to the case where coaxial cables are used, thereby shortening the transmission distance for the test signals and device signals.

In conventional test systems, when making the device board 210 detachable, it is common to use a Low Insertion Force (LIF) connector. However, such LIF connectors exhibit a significant loss of approximately −3 dB in frequency bands above 14 GHz and may cause waveform distortion during high-speed transmission at 28 Gbps or 40 Gbps. By using an FPC cable 222 for the wiring 220, the LIF connector becomes unnecessary, thereby suppressing waveform distortion caused by high-frequency attenuation and enabling accurate testing.

More specifically, the device board 210 includes a socket 212 and a socket PCB 214. The socket PCB 214 is a multilayer board comprising wiring layers and insulating layers. The wiring layers include traces for transmitting signals in the horizontal direction, while the insulating layers include via holes VH for transmitting signals in the vertical direction. It is preferable that the paths through which test signals and device signals are transmitted be drawn out to the rear surface of the device board 210 without substantial horizontal (X and Y direction) routing. On the other hand, for power signals and control signals of lower frequency, routing in the horizontal direction within the socket PCB 214 is permissible.

The FPC cable 222 and the device board 210 are connected by a socket board-side connector 216. The socket board-side connector 216 includes an interposer 218 and a cable clamp 219.

The interposer 218 and the socket PCB 214 are structured to be detachable. Electrodes exposed on the surface of the interposer 218 are electrically connected to electrodes exposed on the rear surface of the socket PCB 214. The FPC cable 222 is clamped by the cable clamp 219 in a state of being in contact with the rear surface electrodes of the interposer 218.

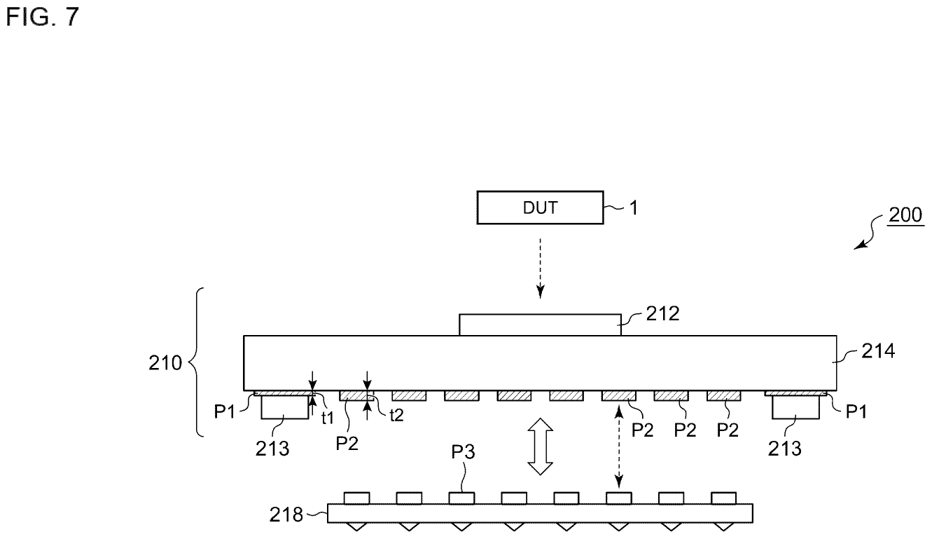

FIG. 7 is a cross-sectional view of the device board 210 according to the embodiment. On the first surface of the socket PCB 214 of the device board 210, the socket 212 is provided and connected to the DUT. The second surface of the device board 210 is structured to be detachably connected to the interposer 218.

On the second surface side of the device board 210, surface mount devices (SMDs) 213 are mounted. Examples of the SMDs 213 include chip capacitors, chip resistors, and chip inductors. On the second surface of the socket PCB 214, a plurality of first pads (lands) P1 for mounting the SMDs 213 are formed.

In addition, on the second surface of the socket PCB 214, a plurality of second pads P2 that serve as electrical contacts with the interposer 218 are formed. The second pads P2 are electrically connected to corresponding contacts (pins) P3 of the interposer 218.

The first pads P1 have a thickness t1, and the second pads P2 have a thickness t2, where the thicknesses t1 and t2 of the two types of pads P1 and P2 differ from each other (t1≠t2). Specifically, the relationship t2>t1 holds.

Preferably, the thickness t2 of the second pads P2 is at least twice the thickness t1 of the first pads P1. More preferably, the thickness t2 of the second pads P2 is at least five times the thickness t1 of the first pads P1. Still more preferably, the thickness t2 of the second pads P2 is at least eight times the thickness t1 of the first pads P1.

For example, the thickness t1 of the first pads P1 is 0.03 microns, with a dimensional tolerance of ±30%. In contrast, the thickness t2 of the second pads P2 is 0.5 microns, also with a dimensional tolerance of ±30%. In this case, the thickness t2 of the second pads P2 is sixteen times the thickness t1 of the first pads P1.

According to this device board 210, since the first pad P1 for mounting components and the second pad P2 serving as an electrical contact point with the interposer 218 have different thicknesses, the peel strength can be increased with respect to the SMD 213, and as for the electrical contact point with the interposer 218, wear resistance can be enhanced and long-term reliability can be improved.

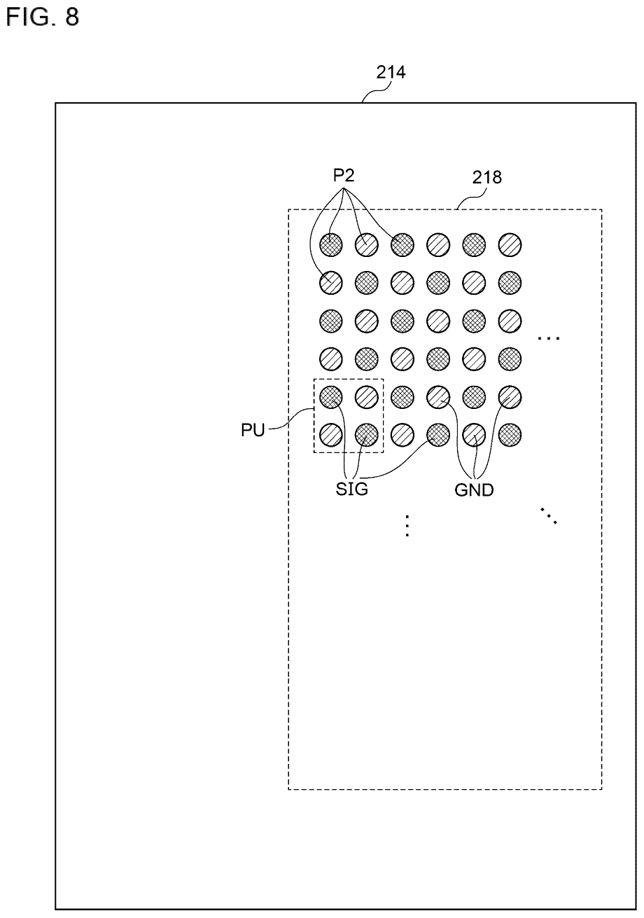

FIG. 8 is a diagram illustrating a layout of the plurality of second pads P2 on the second surface of the socket PCB 214. A plurality of pins (P3 in FIG. 7) arranged in a matrix are provided on the surface of the interposer 218, and a corresponding plurality of second pads P2 are arranged in a matrix on the second surface of the socket PCB 214.

In both the row direction (vertical on the page) and the column direction (horizontal on the page), the plurality of second pads P2 are alternately assigned to signal pins SIG and ground pins GND. In other words, each signal pin SIG is assigned such that ground pins GND are adjacent in the row and column directions, and signal pins SIG are adjacent in the diagonal directions. Alternatively, the arrangement can be understood as consisting of a minimum unit PU of a 2-row by 2-column block, in which two signal pins SIG and two ground pins GND are arranged diagonally. This minimum unit PU is repeatedly arranged in the row and column directions.

The foregoing describes the layout of the second pads P2 on the socket PCB 214. This layout enables a higher signal pin density and a reduction in the area of the socket printed circuit board compared to a layout in which each signal pin is completely surrounded by ground pins in the row, column, and diagonal directions.

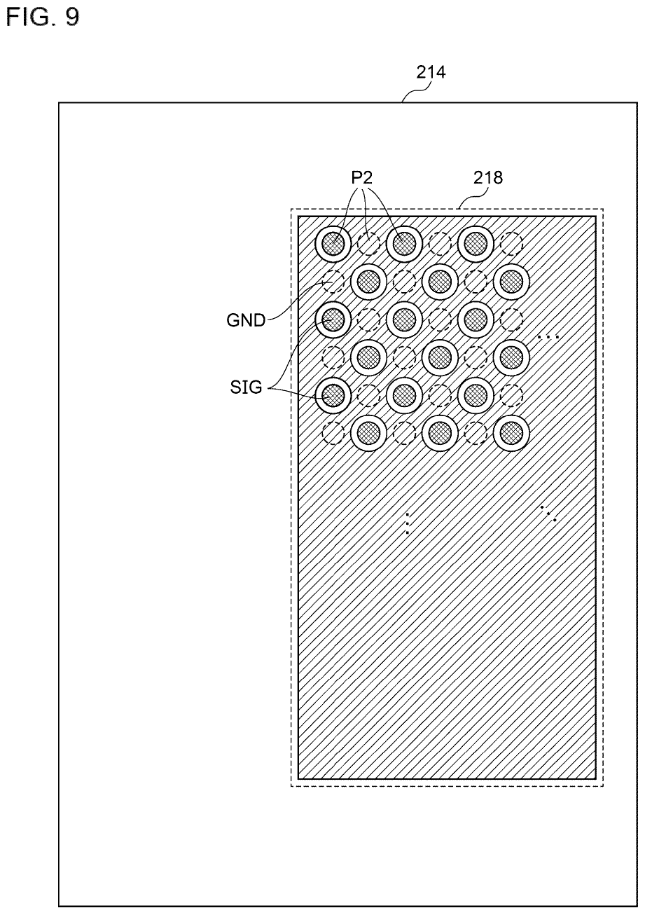

FIG. 9 illustrates a variation of the layout of the plurality of second pads P2 on the second surface of the socket PCB 214. In this variation, among the plurality of second pads P2, the ground pins GND are formed continuously.

According to this variation, the impedance of the ground pins GND can be reduced.

Subsequently, the layout of DUTs and signals on the socket board will be described.

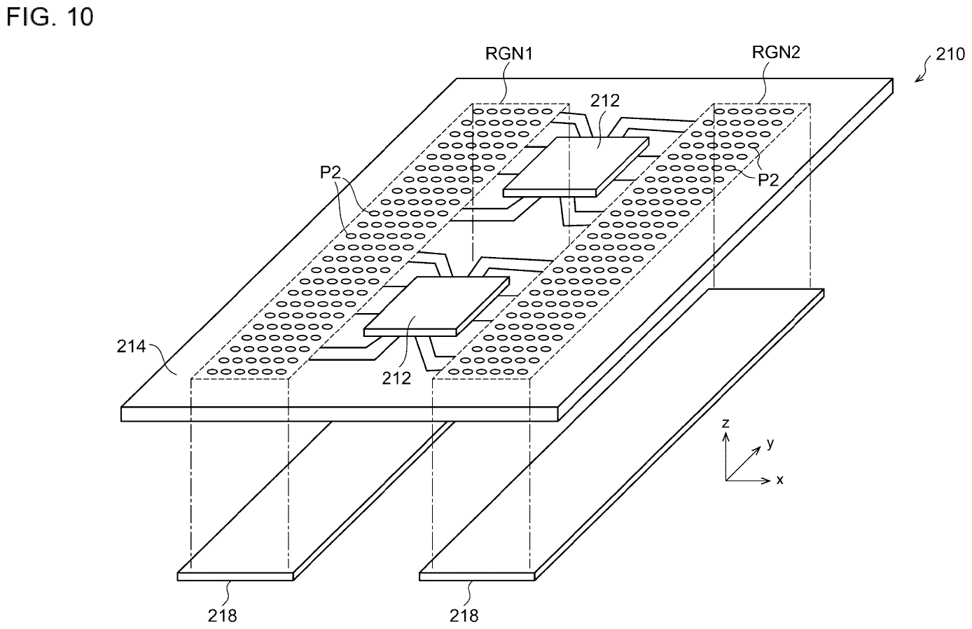

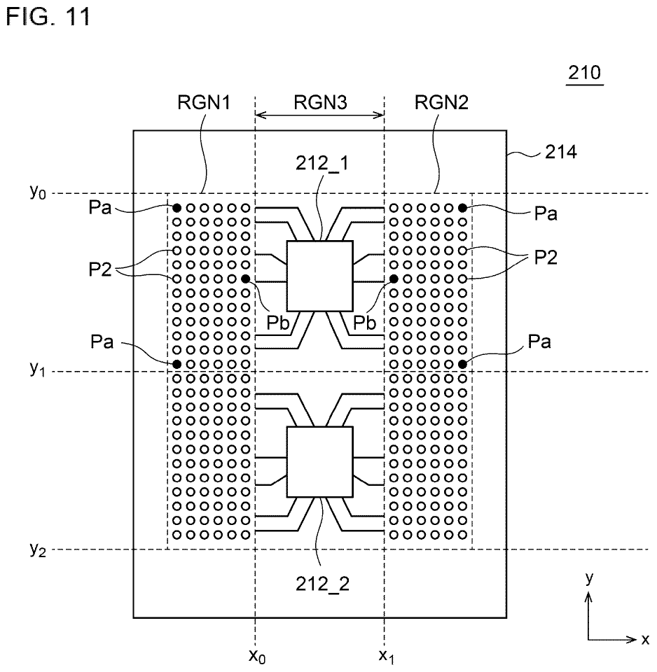

FIG. 10 is a perspective view illustrating the layout of a device board 210 according to an embodiment. FIG. 11 is a plan view illustrating the layout of the device board 210 according to the embodiment.

The device board 210 includes a socket PCB 214 and N socket guides (simply referred to as “sockets”) 212_1 to 212_N. In this example, N equals 2.

The N sockets 212_1 to 212_N are provided on a first surface (upper surface in the figure) of the socket PCB 214.

On a second surface (lower surface in the figure) of the socket PCB 214, a plurality of pads P2 are formed, divided into a first region RGN1 and a second region RGN2. The plurality of pads P2 serve as electrical contact points with the interposer 218.

The first region RGN1 and the second region RGN2 are rectangular in shape, having the same shape and size, and are elongated along a first direction (y). These two regions are spaced apart from each other in a second direction (x).

Each of the N socket guides 212_1 to 212_N is disposed adjacent to each other in a y-direction, in a third region RGN3 that is interposed between the first region RGN1 and the second region RGN2 in an x-direction.

Each of the socket guides 212_1 to 212_N is electrically connected to a portion of the plurality of pads P2 included in the first region RGN1 and a portion of the plurality of pads P2 included in the second region RGN2. Each pin of the socket 212 and its corresponding pad P2 are electrically connected via wirings and via holes provided in the socket PCB 214.

One of the sockets 212_1 is disposed in the range of y₀ to y₁ in the y-direction, and the other socket 212_2 is disposed in the range of y₁ to y₂ in the y-direction. Here, y₀ is a coordinate at one end of the rectangular regions RGN1 and RGN2, y₂ is a coordinate at the other end, and y₁ is a coordinate at the center.

In the layout of FIG. 11, Pa represents the farthest pad among the pads connected to the socket 212_1, and Pb represents the nearest pad among the pads connected to the socket 212_1.

The foregoing describes the layout of the device board 210. The advantages of this device board 210 become apparent through comparison with comparative technology.

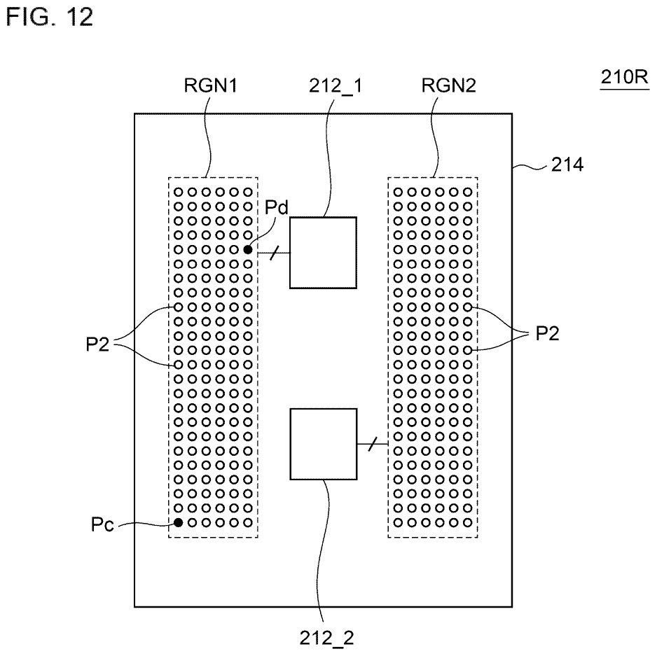

FIG. 12 is a plan view showing a layout of a device board 210R according to comparative technology.

In this comparative technology, one of the sockets 212_1 is connected to the pads P2 included in the first region RNG1, and the other socket 212_2 is connected to the pads P2 included in the second region RNG2.

In the layout shown in FIG. 12, Pc represents the farthest pad among the pads connected to the socket 212_1, and Pd represents the closest pad among the pads connected to the socket 212_1.

By comparing FIG. 11 (embodiment) and FIG. 12 (comparative example), it can be understood that the wiring length from the socket to the farthest pad is shorter in FIG. 11 (embodiment). As a result, parasitic impedance is reduced, allowing for a wider bandwidth and enabling the testing of higher-speed signals.

Further, by comparing FIG. 11 (embodiment) and FIG. 12 (comparative example), it can be seen that the difference between the distance Pa to the farthest pad and the distance to the nearest pad Pb in FIG. 11 (embodiment) is smaller than the difference between the distance Pc to the farthest pad and the distance to the nearest pad Pd in FIG. 12 (comparative example). In other words, according to the embodiment, the wiring lengths to the plurality of pins P2 can be made more uniform compared to the comparative example.

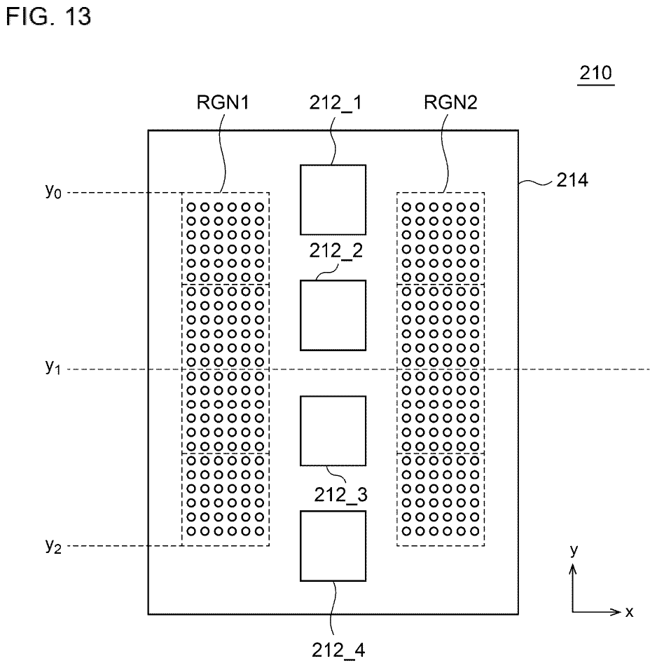

FIG. 13 is a plan view illustrating the layout of a device board 210 according to a modified example. In this modified example, the number N of sockets 212 is four. In this layout, the two central sockets 212_2 and 212_3 are disposed such that, in the Y-direction, they fall within the range y₀ to y₂ of the rectangular regions RGN1 and RGN2. Accordingly, advantages similar to those of the layout shown in FIG. 10 can be achieved.

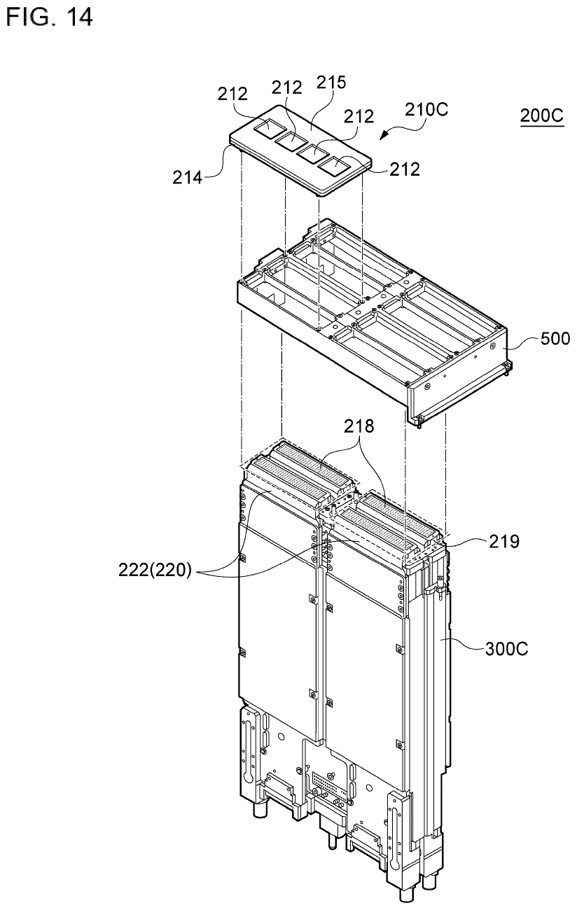

FIG. 14 is an exploded perspective view of an interface device 200C according to an embodiment. FIG. 14 shows a device board 210C, a front-end module 300C, and an FEU (front-end unit) frame 500.

The front-end module 300 is attached to the FEU frame 500 to be supported and fixed. In this example, two front-end modules 300 are attached to one FEU frame 500.

The device board 210C includes a socket PCB (Printed Circuit Board) 214, a plurality of sockets 212, and a socket guide (frame) 215 which is a mechanical component. The socket PCB 214 and the socket guide 215 have the same shape as each other and have a rectangular shape in a plan view. The device board 210C is mechanically connected to the FEU frame 500 and electrically connected to the front-end module 300C.

The front-end module 300 includes an FPC cable 222. The FPC cable 222 is electrically connected to a pad on a back surface of the socket PCB 214 of the device board 210C via an interposer 218.

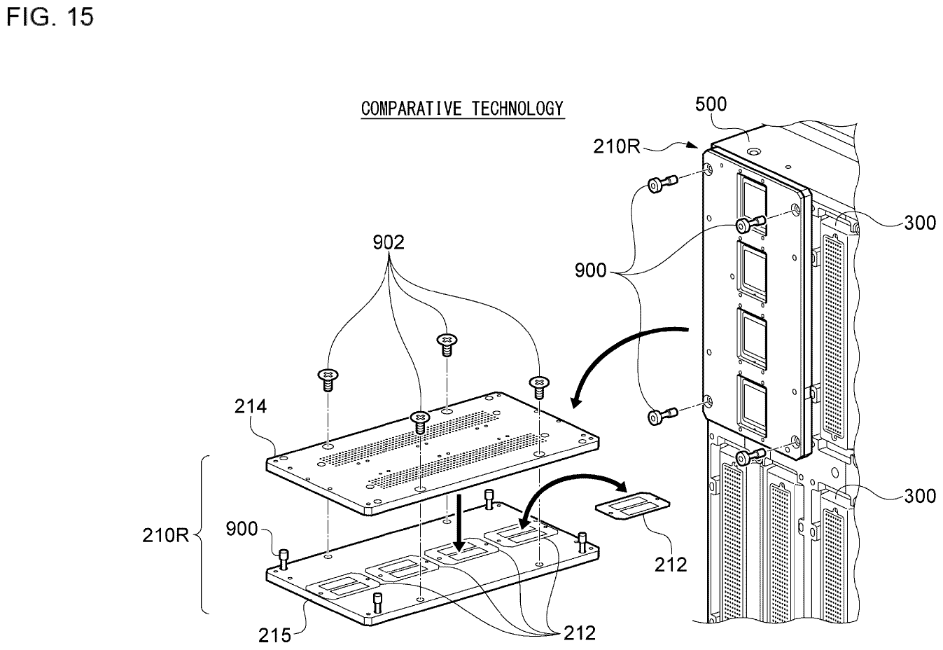

FIG. 15 is a diagram illustrating connection between a device board and a front-end module according to a comparative technology studied by the inventors of the present disclosure. The front-end module 300 is assembled to the FEU frame 500. The device board 210R is fixed to the FEU frame 500 by screws 900.

The device board 210R includes a plurality of sockets 212, a socket PCB (Printed Circuit Board) 214, and a socket guide 215. The socket guide 215 and the socket PCB 214 are coupled by screws 904 in a state where the socket 212 is sandwiched therebetween.

In the device board 210R, the socket 212 is replaceable so as to measure DUTs having different pin assignments or to be replaced with a new one when worn. In the configuration of FIG. 15, in order to replace the socket 212, it is necessary to remove the entire device board 210R from the FEU frame 500 and then disassemble the device board 210R to replace the socket 212. This increases the labor of an operator, and it can be said that maintainability is poor.

Next, a device board 210C having excellent maintainability will be described.

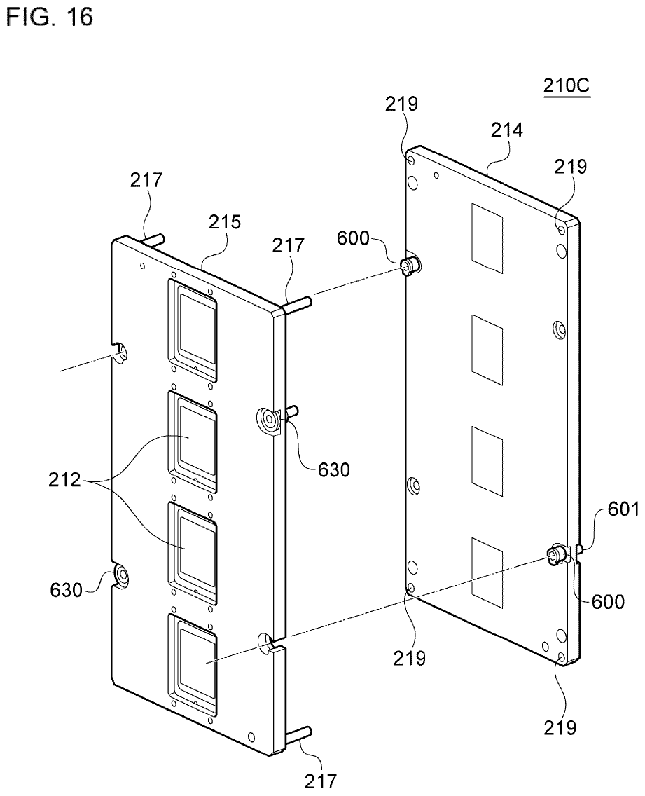

FIG. 16 is an exploded perspective view of a device board 210C according to an embodiment. Unevenness, grooves, openings, and the like for positioning and fixing a plurality of sockets 212 are formed in a socket guide 215. The plurality of sockets 212 are fixed in a state where the plurality of sockets 212 are sandwiched between the socket guide 215 and a socket PCB 214.

The socket guide 215 includes one or more pins 217. An opening 219 is provided in the socket PCB 214 at a position corresponding to the pin 217, and the pin 217 is insertable through the opening 219. An opening is also provided in the FEU frame 500 to which the device board 210C is attached, and the pin 217 is also inserted into the opening of the FEU frame 500. The pin 217 performs in-plane positioning of the socket guide 215, the socket PCB 214, and the FEU frame 500.

The device board 210C according to the embodiment is configured such that the socket 212 is replaceable by removing only the socket guide 215 while the socket PCB 214 remains attached to the FEU frame 500.

Specifically, the device board 210C includes a locking mechanism 600 in addition to the socket PCB 214 and the socket guide 215.

The locking mechanism 600 is switchable between at least a first state φ1 and a second state φ2. The locking mechanism 600 is configured to provide a state in which the socket PCB 214 and the socket guide 215 are coupled to each other in the first state φ1, and to be capable of releasing the coupling between the socket PCB 214 and the socket guide 215 as well as providing a state in which the socket PCB 214 and an FEU frame 500 (not shown in FIG. 16) of the automatic test apparatus are coupled to each other in the second state φ2.

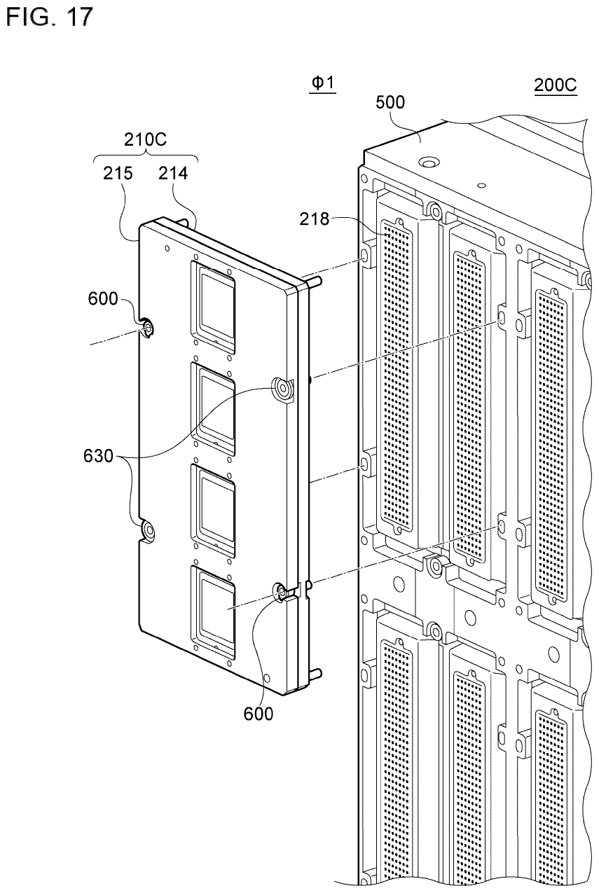

FIG. 17 is a perspective view showing the device board 210C in the first state φ1. In the first state φ1, the coupling between the socket PCB 214 and the socket guide 215 is maintained by the locking mechanism 600, and the coupling between the socket PCB 214 and the FEU frame 500 is released. The socket guide 215 and the socket PCB 214 of the device board 210C are fixed by being fastened together to the FEU frame 500 by screws which are auxiliary locking mechanisms 630. By loosening the screws 630 in the first state φ1, the socket PCB 214 and the socket guide 215 can be removed from the FEU frame 500 while remaining integrated.

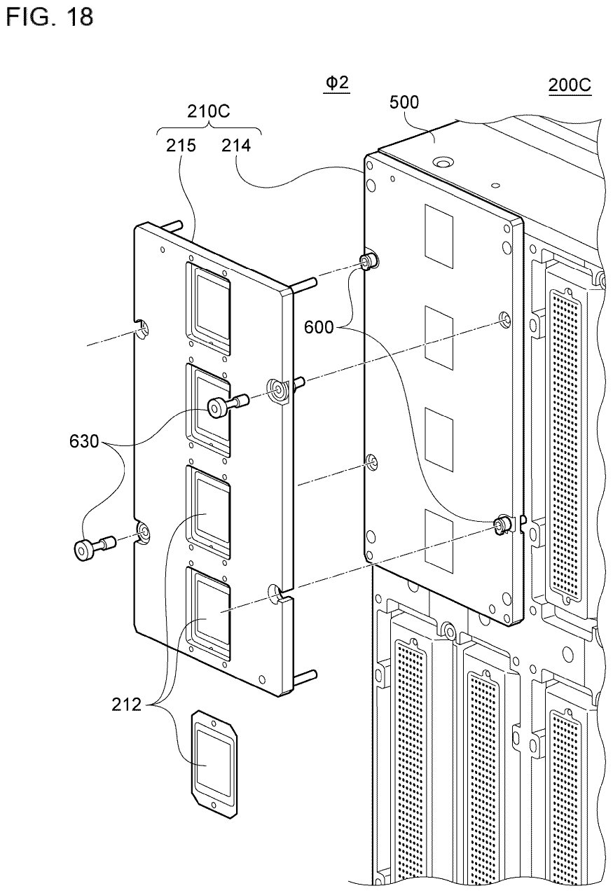

FIG. 18 is a perspective view showing the device board 210C in the second state φ2. In the second state φ2, the coupling between the socket PCB 214 and the socket guide 215 is released by the locking mechanism 600 while maintaining the coupling between the socket PCB 214 and the FEU frame 500. By loosening the screws 630 in this state, only the socket guide 215 can be removed while the socket PCB 214 remains fixed to the FEU frame 500. In this state, an operator can replace the socket 212.

As described above, according to the present embodiment, the socket 212 can be replaced by removing only the socket guide 215 without removing the entire device board 210C from the FEU frame 500 of the automatic test apparatus, which can reduce the labor of an operator and improve maintainability compared to the comparative technology.

The two locking mechanisms 600 and the two auxiliary locking mechanisms 630 are respectively provided at edges extending parallel to each other along a longitudinal direction of the device board 210C and are arranged at vertices of a rectangle. The two locking mechanisms 600 are arranged at a first diagonal of the rectangle, and the two auxiliary locking mechanisms 630 are arranged at a second diagonal. Specifically, one locking mechanism 600 and one auxiliary locking mechanism 630 are provided at each edge. The locking mechanism 600 and the auxiliary locking mechanism 630 provided at each edge are provided at a predetermined interval from each other. The locking mechanism 600 provided at one edge and the auxiliary locking mechanism 630 provided at the other edge are provided at the same position as each other in the longitudinal direction. The two locking mechanisms 600 and the two auxiliary locking mechanisms 630 are arranged such that a straight line connecting the locking mechanisms 600 provided at the respective edges and a straight line connecting the auxiliary locking mechanisms 630 provided at the respective edges intersect each other. With this arrangement, stress can be dispersed, distortion or warpage of the socket PCB 214 can be suppressed, and pads on the back surface of the socket PCB 214 and pads of the interposer 218 can be brought into appropriate contact with each other.

Next, a specific configuration example of the locking mechanism 600 will be described.

The locking mechanism 600 in FIG. 16 may be a rotatable lock pin 600A. The lock pin 600A has an end 601 protruding from the socket board side. When the lock pin 600A is at a predetermined first angular position θ1 corresponding to the first state φ1, the lock pin 600A maintains a state in which the socket PCB 214 and the socket-board-side connector 216 are coupled to each other. When the lock pin 600A is at a predetermined second angular position θ2 corresponding to the second state φ2, the end 601 engages with the FEU frame 500, and the coupling between the socket PCB 214 and the socket guide 215 is released.

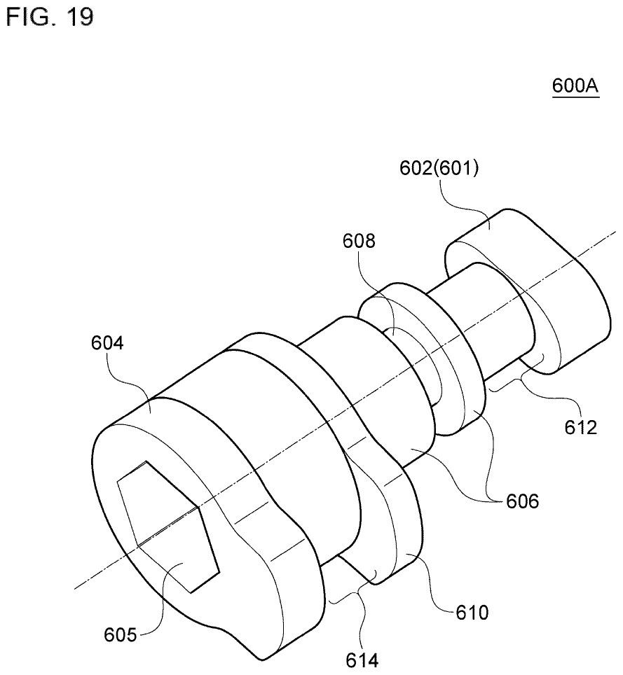

FIG. 19 is a perspective view showing a lock pin 600A which is a locking mechanism 600. The lock pin 600A mainly includes a frame lock key 602 corresponding to the end 601, a socket guide lock key 604, and a rotation shaft 606.

The rotation shaft 606 fits into an opening (bearing) provided in the socket PCB 214 and rotates with respect to the socket PCB 214.

A frame lock key 602 corresponding to the end 601 is provided at one end side of the rotation shaft 606. The frame lock key 602 has a first shape in a cross section viewed along the rotation shaft. The frame lock key 602 is insertable into and removable from a frame keyhole 640 provided in the FEU frame 500 when at a predetermined first angular position θ1, and is lockable with respect to the frame keyhole 640 so that the lock pin 600A does not come out of the FEU frame 500 when at a predetermined second angular position θ2 corresponding to the second state φ2.

A socket guide lock key 604 is provided at the other end side of the rotation shaft 606. The socket guide lock key 604 has a second shape in a cross section viewed along the rotation shaft. The second shape may be identical to the first shape.

The frame lock key 602 and the socket guide lock key 604 rotate together with the rotation shaft 606. A hole 605 that fits with a fastening tool such as a hex wrench or a screwdriver is formed in the socket guide lock key 604. By inserting the fastening tool into the hole 605 and rotating the rotation shaft 606, the rotation angular position can be changed.

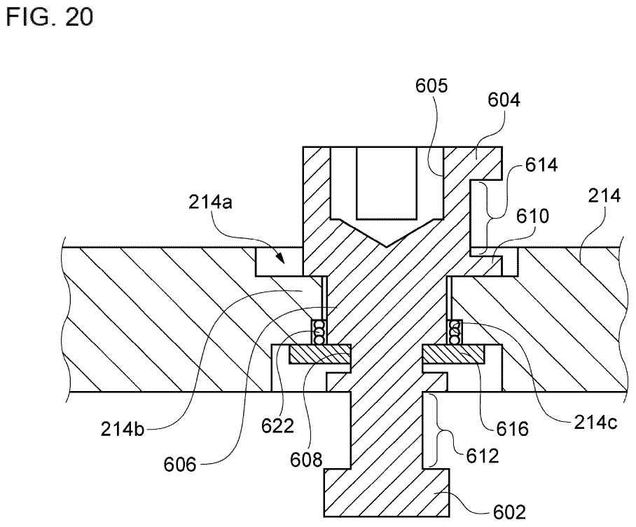

A groove 608 for an E-ring and a stopper 610 are formed on the rotation shaft 606, and the socket PCB 214 is sandwiched by the stopper 610 and an E-ring 616 (shown in FIG. 20) mounted in the groove 608.

A portion 612 sandwiched between the rotation shaft 606 and the frame lock key 602 fits with the FEU frame 500 (not shown in FIG. 19). In addition, a portion 614 sandwiched between the socket guide lock key 604 and the stopper 610 fits with the socket guide 215 (not shown in FIG. 19).

FIG. 20 is a cross-sectional view of the socket PCB 214 to which the lock pin 600A is attached. The socket PCB 214 has a hole 214a into which the lock pin 600A is inserted. The hole 214a is formed to penetrate the socket PCB 214 in a thickness direction. A convex portion 214b is provided on an inner peripheral surface of the hole 214a, for example, over the entire circumference. The convex portion 214b is provided at a position at a predetermined distance from both ends of the hole 214a and protrudes toward an axis of the hole 214a. The convex portion 214b has a notched portion 214c. The notched portion 214c is provided at one end on the side of the frame lock key 602 in a state where the lock pin 600A is inserted into the hole 214a. The notched portion 214c is formed in a concave shape over the entire circumference of the convex portion 214b in a direction moving away from the axis of the hole 214a and accommodates a spring 622 described later. The lock pin 600A is supported at the stopper 610 on a surface of the convex portion 214b facing the side opposite to the frame lock key 602. A groove 608 is formed in the lock pin 600A over the entire circumference. In a state where the lock pin 600A is inserted into the hole 214a, by inserting the E-ring 616 into the groove 608, the lock pin 600A is attached to the socket PCB 214 at the convex portion 214b such that relative movement is impossible, for example, in the axial direction. The spring 622 is accommodated in the notched portion 214c. The spring 622 is, for example, a compression coil spring and is provided so as to surround the rotation shaft 606. One end of the spring 622 is supported on a surface of the notched portion 214c facing the axial direction of the hole 214a. The spring 622 is pressed at the other end side by the E-ring 616 so as to be compressed toward the convex portion 214b. The spring 622 urges the E-ring 616 toward the frame lock key 602, the lock pin 600A is pulled toward the frame lock key 602 side, and the stopper 610 is pressed against the convex portion 214b. Unintentional rotation of the lock pin 600A is prevented by a frictional force generated between the convex portion 214b and the stopper 610 by an action of the force from the spring 622 along the axial direction.

Next, the operation of the lock pin 600A will be described.

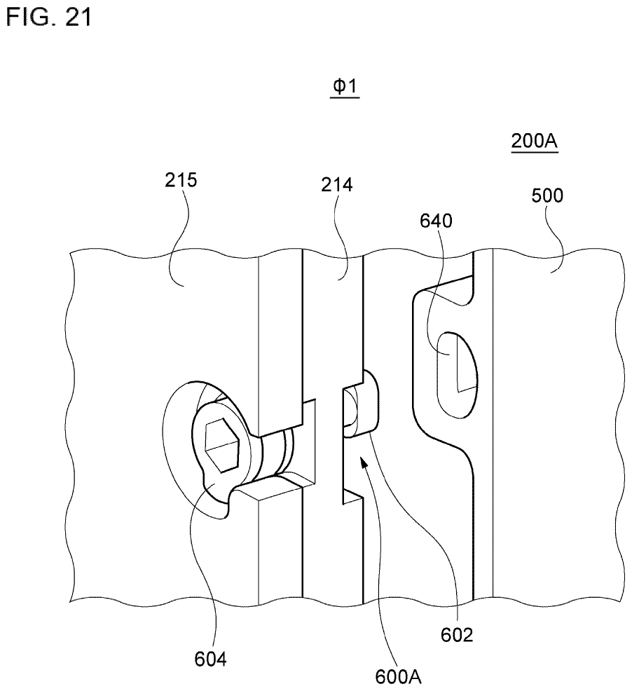

FIG. 21 is a perspective view showing a state of the interface apparatus 200A in the first state φ1. A frame keyhole 640 is formed in the FEU frame 500 at a position corresponding to the lock pin 600A. The frame keyhole 640 has a shape corresponding to the first shape of the frame lock key 602, and the frame lock key 602 can be inserted into and removed from the frame keyhole 640 when the lock pin 600A is at a first angular position corresponding to the first state φ1. That is, in the first state φ1, the FEU frame 500 and the socket PCB 214 (device board 210A) are in a state in which they are not coupled or locked to each other via the lock pin 600A (hereinafter, also referred to as an “unlocked state”).

When the lock pin 600A is rotated to another rotation angular position in a state where the lock pin 600A is set at the first angular position and the frame lock key 602 is inserted through the frame keyhole 640, the frame lock key 602 and the frame keyhole 640 enter an engaged state. In this state, the FEU frame 500 and the socket PCB 214 (device board 210A) are in a state in which they are coupled or locked to each other via the lock pin 600A (hereinafter, also referred to as a “locked state”).

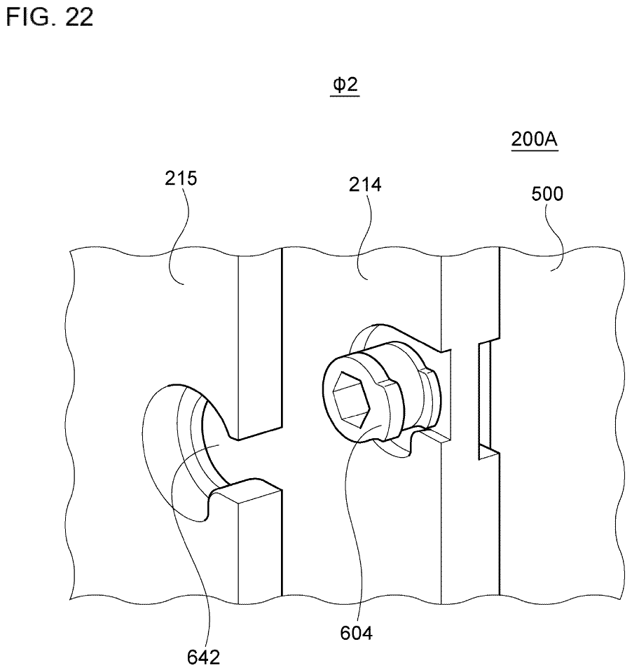

FIG. 22 is a perspective view showing a state of the interface apparatus 200A in the second state φ2. A socket guide keyhole 642 is formed in the socket guide 215 at a position corresponding to the lock pin 600A. The socket guide keyhole 642 has a shape corresponding to the second shape of the socket guide lock key 604, and the socket guide lock key 604 can be inserted into and removed from the socket guide keyhole 642 when the lock pin 600A is at a second angular position corresponding to the second state φ2. That is, in the second state φ2, a state between the socket PCB 214 and the socket guide 215 is an unlocked state.

When the lock pin 600A is rotated to another rotation angular position in a state where the lock pin 600A is set at the second angular position and the socket guide lock key 604 is inserted through the socket guide keyhole 642, the socket guide lock key 604 and the socket guide keyhole 642 enter an engaged state, resulting in a locked state.

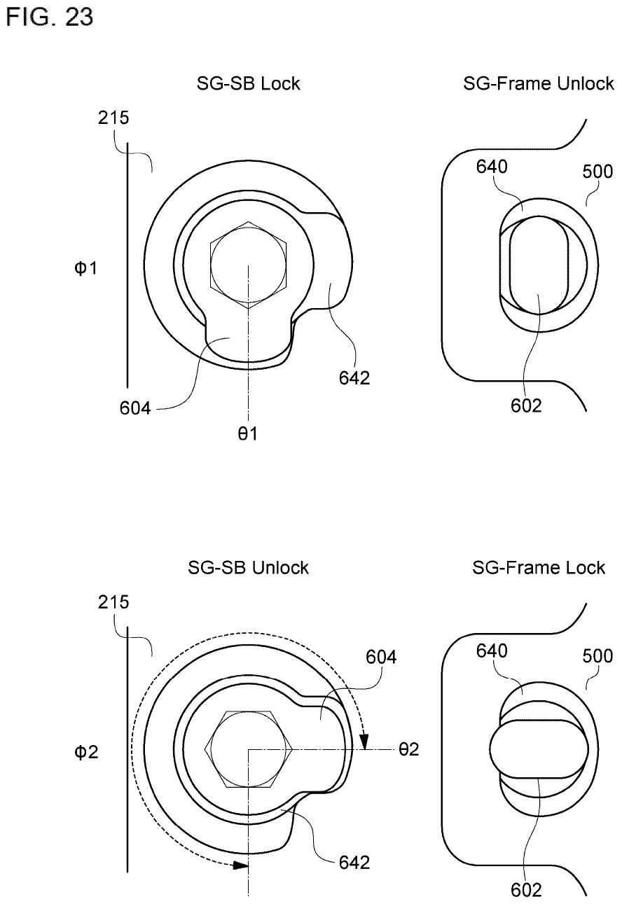

FIG. 23 is a diagram for explaining the first state φ1 and the second state φ2 of the lock pin 600A. The upper part of FIG. 23 shows the first state φ1. In the first state φ1, the lock pin 600A is at the first angular position θ1, and the socket PCB 214 and the socket guide 215 are in the locked state. On the other hand, the frame lock key 602 and the frame keyhole 640 are not engaged, and therefore the socket PCB 214 and the FEU frame 500 are in the unlocked state.

The lower part of FIG. 23 shows the second state φ2. In the second state φ2, the lock pin 600A is at the second angular position θ2, and the socket PCB 214 and the socket guide 215 are in the unlocked state. On the other hand, the frame lock key 602 and the frame keyhole 640 are in the locked state.

Here, the rotatable range of the lock pin 600A is limited, and the first angular position θ1 and the second angular position θ2 are located at both ends of the rotatable range of the lock pin 600A. This uniquely determines the respective angular positions θ1 and θ2, thereby improving the workability of switching between the first state φ1 and the second state φ2. Preferably, the first angular position θ1 and the second angular position θ2 should be separated by 180° or more, and more preferably by approximately 250° to 290°. In the example of FIG. 23, the two angular positions θ1 and θ2 are separated by 270°. Note that the first angular position θ1 may be any position within the rotation range of the lock pin 600A where the first state φ1 is maintained between the first state φ1 and the second state φ2. That is, the first angular position θ1 may be any position where the coupling between the socket PCB 214 and the FEU frame 500 is released while the state in which the socket PCB 214 and the socket guide 215 are coupled to each other via the lock pin 600A is maintained when the lock pin 600A is rotated. As a result, work accuracy during insertion and processing tolerances are relaxed.

Furthermore, when the device board 210C is installed vertically, the positional relationship between the first angular position θ1 and the second angular position θ2 is as shown in FIG. 23. In this state, when trying to rotate the lock pin 600A from the first angular position θ1 to the second angular position θ2, it is necessary to rotate the lock pin 600A upward clockwise once against the direction of gravity (downward in FIG. 23). In addition, when trying to rotate the lock pin 600A from the second angular position θ2 to the first angular position θ1, it is necessary to rotate the lock pin 600A upward counterclockwise once against the direction of gravity (downward in FIG. 23). Thus, even if vibration or the like acts on the device board 210C, the lock pin 600A tends to remain at the first angular position θ1 or the second angular position θ2 due to the action of gravity, and unintentional switching between the first state φ1 and the second state φ2 is prevented.

### Modification 1

The configuration of the locking mechanism 600 is not limited to the rotary lock pin 600A described in the embodiment. As the locking mechanism 600, it is possible to employ other structures capable of taking at least two states, such as a push-type latch.

### Modification 2

In the embodiment, the device board 210C and the FEU frame 500 are mechanically coupled by the combination of the locking mechanism 600 and the auxiliary locking mechanism 630; however, the auxiliary locking mechanism 630 may be omitted, and the device board 210C and the FEU frame 500 may be coupled only by the locking mechanism 600. For example, the locking mechanism 600 may be configured to enable a third state φ3 in addition to the first state φ1 and the second state φ2. In the third state φ3, the socket PCB 214 and the socket guide 215 may be in the locked state via the locking mechanism 600, and the socket PCB 214 and the FEU frame 500 may also be in the locked state. In the case of the lock pin 600A, an angular position θ3, where θ3≠θ1≠θ2, can be associated with the third state φ3.

Various types of interface devices 200 exist, and the present disclosure is applicable to any of these types.

### SBC (Socket Board Change) Type

The SBC type is an interface device in which the device board 210 is replaced in accordance with the type of DUT.

### CLS (Cable Less) Type

The CLS type is an interface device in which the upper part (a device specific adapter, or DSA) and the lower part (a motherboard) of the interface device 200 are separable, and the DSA is replaced according to the type of DUT. When the interface device 200 according to the present embodiment is applied to the CLS type, two configurations are possible.

In one configuration, the front-end module 300 is disposed on the motherboard side. In this case, the front-end module 300 can be shared across different DUT tests, which is advantageous from a cost perspective.

In another configuration, the front-end module 300 is disposed on the DSA side. In this case, although the front-end module 300 must be provided for each DSA, which increases the overall cost of the apparatus, the front-end module 300 can be placed closer to the DUT, which is advantageous for high-speed testing.

### CCN (Cable Connection) Type

The CCN type is an interface device in which the entire interface device 200 is replaced according to the type of DUT. When the interface device 200 according to the present embodiment is applied to the CCN type, the front-end module 300 can be positioned extremely close to the DUT, which is advantageous for high-speed testing.

### Wafer Motherboard

The interface device 200 may be a wafer motherboard used for wafer-level testing. In this case, the interface device 200 may include a probe card in place of the socket board.

The above-described embodiments are illustrative, and it will be understood by those skilled in the art that various modifications can be made to the combinations of the individual components and processing steps. Several such modified examples will be described below.

### Modified Example 1

In the embodiment, the pin electronics ICs 400 are electrically connected to the FPC and the printed circuit board via an interposer. However, the present disclosure is not limited thereto. Instead of using an FPC cable 222 as the wiring 220, a printed circuit board or other types of wiring may be used.

### Modified Example 2

In the embodiment, the interface device 200 is described as having the device board 210 arranged parallel to the ground. However, the present disclosure is not limited thereto. For example, the device board 210 may be oriented vertically with respect to the ground. In that case, the Y direction in FIG. 4 and FIG. 5 corresponds to the direction of gravity.

While the preferred embodiments of the present disclosure have been described using specific terms, such description is for illustrative purposes only, and it is to be understood that changes and variations may be made without departing from the spirit or scope of the appended claims.

What is claimed is:

1. A device board detachable from a frame of an automatic test apparatus, comprising:
a socket board;
a socket guide; and
a locking mechanism structured to switch between at least a first state and a second state, the locking mechanism being configured to couple the socket board and the socket guide to each other in the first state, and the locking mechanism being configured to decouple the socket board from the socket guide and couple the socket board to the frame of the automatic test apparatus in the second state.

2. The device board according to claim 1, wherein the locking mechanism is a rotatable lock pin, and the lock pin includes an end portion protruding from a side of the socket board, the lock pin being structured to maintain a state in which the socket board and the socket guide are coupled to each other when the lock pin is at a predetermined first angular position corresponding to the first state, and the lock pin being configured to engage the end portion with the frame and decouple the socket board from the socket guide when the lock pin is at a predetermined second angular position corresponding to the second state.

3. The device board according to claim 1, wherein: the locking mechanism is a rotatable lock pin, and
the lock pin includes:
a frame lock key structured to be insertable into and removable from a frame keyhole provided in the frame when the lock pin is at a predetermined first angular position corresponding to the first state, the frame lock key being configured to be lockable to the frame keyhole when the lock pin is at a predetermined second angular position corresponding to the second state; and
a socket guide lock key structured to be insertable into and removable from a socket guide keyhole provided in the socket guide when the lock pin is at the second angular position, the socket guide lock key being configured to be lockable to the socket guide keyhole when the lock pin is at the first angular position.

4. The device board according to claim 2, wherein a rotatable range of the lock pin is limited, and the first angular position and the second angular position are located at both ends of the rotatable range of the lock pin.

5. The device board according to claim 1, wherein openings are formed in the socket board and the socket guide at positions corresponding to screw holes provided in the frame, and the socket guide and the socket board are configured to be fastened together to the frame by screws.

6. The device board according to claim 5, wherein the socket board includes two locking mechanisms,
the socket guide and the socket board are configured to be fastened together to the frame by two screws, and
the two locking mechanisms are arranged at a first diagonal of a rectangle, and the two screws are arranged at a second diagonal of the rectangle.

7. An automatic test apparatus comprising the device board according to claim 1.

8. A lock pin for use with a socket board and a socket guide to constitute a device board, the lock pin comprising:
a frame lock key structured to be rotatably attachable to the socket board, the frame lock key being configured to be insertable into and removable from a frame keyhole provided in a frame when the lock pin is at a predetermined first angular position corresponding to a first state, and the frame lock key being configured to be lockable to the frame keyhole when the lock pin is at a predetermined second angular position corresponding to a second state; and
a socket guide lock key structured to be insertable into and removable from a socket guide keyhole provided in the socket guide when the lock pin is at the second angular position, and the socket guide lock key being configured to be lockable to the socket guide keyhole when the lock pin is at the first angular position.

9. A socket board configured to be attachable with the lock pin according to claim 8.
